(19) United States
(12) Patent Application Publication
(10) Pub. No.: US 2009/0186588 A1
(43) Pub. Date: Jul. 23, 2009

(54) Method and apparatus for determining context information using electromagnetic interference patterns

(75) Inventors: Jakke S. Makela, Turku (FI); Niko S. Porjo, Piikkio (FI)

Correspondence Address: HARRINGTON & SMITH, PC, 4 RESEARCH DRIVE, Suite 202, SHELTON, CT, 06484-6212, US

(73) Assignee: Nokia Corporation

(21) Appl. No.: 12/009,400

(22) Filed: Jan. 18, 2008

(51) Int. Cl. H04B 17/00; G01R 29/08

(52) U.S. Cl. 455/226.1; 324/612

(57) ABSTRACT

The exemplary embodiments of this invention describe a method for determining context information using EMI patterns. The method includes determining emitter information of a measured interference signal. A context is determined based upon the emitter information. Determining the interference signal emitter may also include comparing the measured interference signal to known interference signals. At least one setting of a device may be changed based upon the determined context. Various embodiments of apparatus are also described.

### TECHNICAL FIELD

The exemplary embodiments of this invention relate generally to measuring electromagnetic interference and, more specifically, relate to determining context information using signal waveforms derived from electromagnetic interference.

### BACKGROUND

Context sensing is a growing application area. Context sensing generally focuses on determining the environment (i.e., context) in which an application (or device) may find itself. While there is much interest in this area, there have not been many practical applications. This is due at least in part to the cost of the needed sensors.

In general electromagnetic compatibility/electromagnetic interference (EMC/EMI) research relates to the protection of devices from sources of electromagnetic radiation. Currently a radio antenna and an audio codec may be used to create a lightning-detection system.

For many lightning detectors the objective is to locate some pre-specified signal which is to be filtered out from among the EMI disturbance sources. For example, there may be a well-identified source signal (S), on which a transmission channel introduces noise (N) leading to a measured signal (M).

Usually, it is not possible to know what the original signal S in fact was, but nevertheless the transmission quality can be indirectly measured (e.g., by the accuracy of the lightning detection).

In the prior art (e.g., wireless communication), the task has been to determine the signal S based on the measured signal M. In general, the noise N is filtered out and cannot be reconstructed from the final signal (e.g., the digitized bits of a digital communication signal).

Consider WO2007042600, wherein a mobile lightning detector is described that is characterized as being a mobile radio frequency (RF) device. In known mobile RF devices, such as mobile phones, electromagnetic interference in received RF signals is eliminated immediately by filtering. What is described is a “staged-approach” solution in which any interference triggers a low-energy warning mode, and only launches an actual detection mode if certain preconditions are met.

What is needed is a method and apparatus to extend the possible parameters being monitored and to evaluate such electromagnetic interferences.

### SUMMARY

An exemplary embodiment in accordance with this invention provides a method for determining context information using EMI waveform patterns. The method includes determining source information of a measured interference signal. A context is determined based upon the source information.

A further exemplary embodiment in accordance with this invention provides an apparatus for determining context information using EMI waveform patterns. The apparatus includes a unit to measure at least one interference signal and a processing unit. The processing unit determines source information of the measured interference signal and determines a context based upon the source information.

Another exemplary embodiment in accordance with this invention provides an apparatus for determining context information using EMI waveform patterns. The apparatus includes a means for determining source information of a measured interference signal. A means for determining a context based upon the source information is also included. The apparatus also includes a means for setting at least one operating parameter of the apparatus in accordance with the determined context.

A further exemplary embodiment in accordance with this invention provides a computer readable memory tangibly embodying a data structure for determining context information using EMI waveform patterns. The data structure includes interference data representing one or more interference waveforms. Emitter information representative of a source of interference associated with the corresponding interference data is also included. The interference data is usable with a measured interference signal to determine the emitter information. The determined emitter information is usable to determine a context of a device

### BRIEF DESCRIPTION OF THE DRAWINGS

The foregoing and other aspects of embodiments of this invention are made more evident in the following Detailed Description, when read in conjunction with the attached Drawing Figures, wherein:

FIG. 1 shows a simplified block diagram of various electronic devices that are suitable for use in practicing the exemplary embodiments of this invention.

FIG. 2A depicts an exemplary plot of an interference waveform generated by a close lightning flash;

FIG. 2B depicts an exemplary plot of an interference waveform generated by an close intra-cloud flash;

FIG. 2C depicts an exemplary plot of an interference Waveform generated by a distant flash;

FIG. 2D depicts an exemplary plot of an interference waveform generated by a distant intra-cloud lightning flash;

FIG. 3A depicts an exemplary plot of an interference waveform generated by a microwave oven from 2 m away;

FIG. 3B depicts an exemplary plot of an interference waveform generated by a different microwave oven from 2 m away;

FIG. 3C depicts an exemplary plot of an interference waveform generated by a refrigerator;

FIG. 3D depicts an exemplary plot of an interference waveform generated by an LCD monitor at less than 50 cm away;

FIG. 4A depicts an exemplary plot of an interference waveform generated by a light switch which is several meters away;

FIG. 4B depicts an exemplary plot of an interference waveform generated by a fluorescent light which is 1 m away;

FIG. 5A depicts an exemplary plot of an interference waveform measured within a car when the motor is started;

FIG. 5B depicts an exemplary plot of an interference waveform measured within a car while the motor is running;

FIG. 5C depicts an exemplary plot of an interference waveform measured within a car while the motor is running;

FIG. 6 depicts an exemplary plot of an interference waveform generated by a train that is 10 m away;

FIG. 7A depicts an exemplary plot of an interference waveform generated by a GSM phone while there is no call going on;

FIG. 7B depicts an exemplary plot of an interference waveform generated by a GSM phone while making a call;

FIG. 7C depicts an exemplary plot of an interference waveform generated by a GSM phone while active; and

FIG. 7D depicts an exemplary plot of an interference waveform generated by the screen of a phone using a dim backlight.

FIG. 8 shows a simplified logic flow chart of a method in accordance with this invention.

FIG. 9 shows a simplified block diagram of an electronic device that is suitable for use in practicing the exemplary embodiments of this invention.

FIG. 10 shows a simplified block diagram of a computer readable memory that is suitable for use in practicing the exemplary embodiments of this invention.

### DETAILED DESCRIPTION

An exemplary embodiment of this invention provides a method for using a measured interference signal to detect an interference source or sources in the environment (e.g. man-made sources), and to determine the context of an application and/or device, such as a mobile phone.

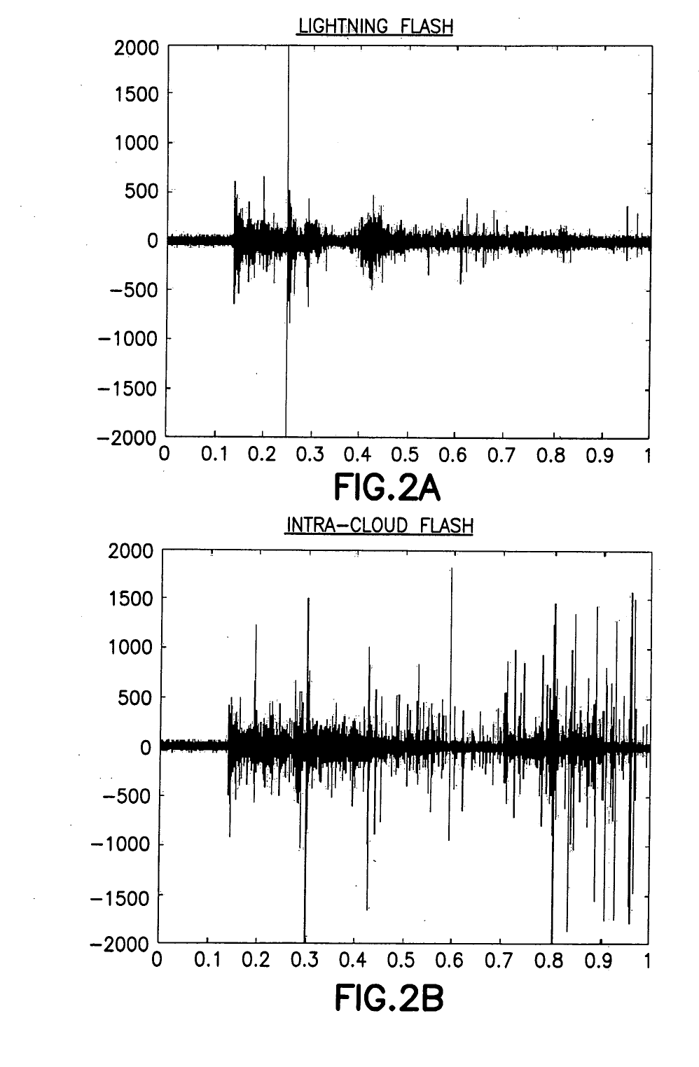

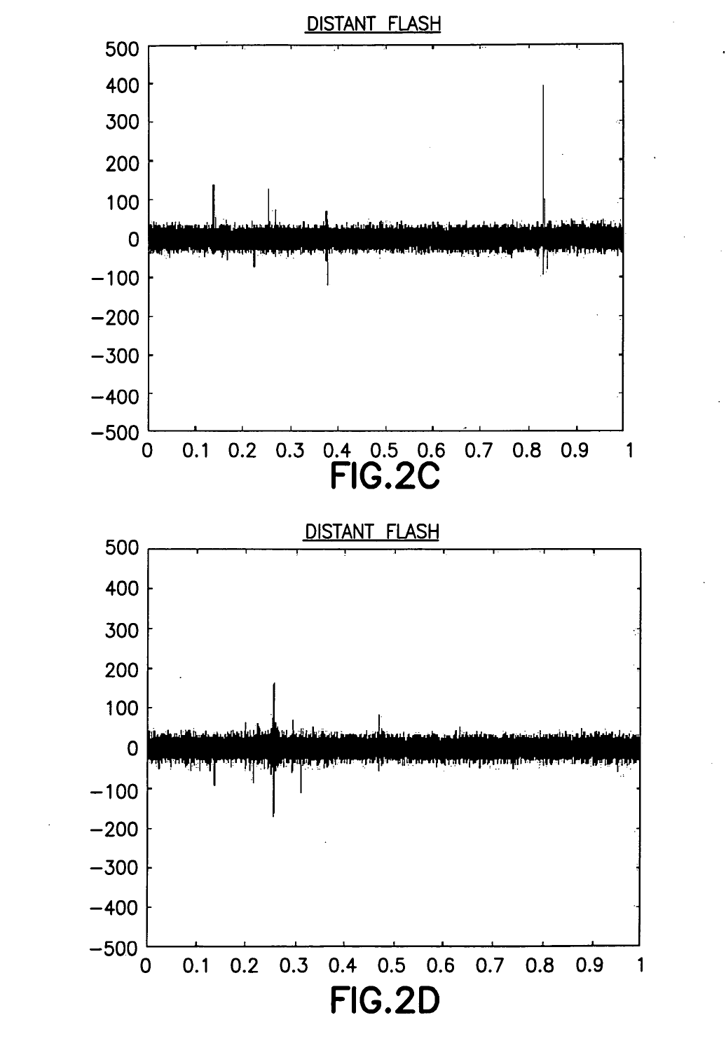

Many devices emit EMI in the MHz range (as well as in other frequencies), which when downmixed yield identifiable audio signals. FIGS. 2-7 show some typical waveforms of exemplary interference sources (the figures are plots of the audio waveform in wav format; the x-axis length is one second).

FIGS. 2A-2D depict exemplary plots of interference waveforms generated from a number of natural sources. In FIG. 2A the source is a close lightning flash and in FIG. 2B it is a close intra-cloud flash, while in FIG. 2C the source is a distant flash and in FIG. 2D it is a distant intra-cloud lightning flash.

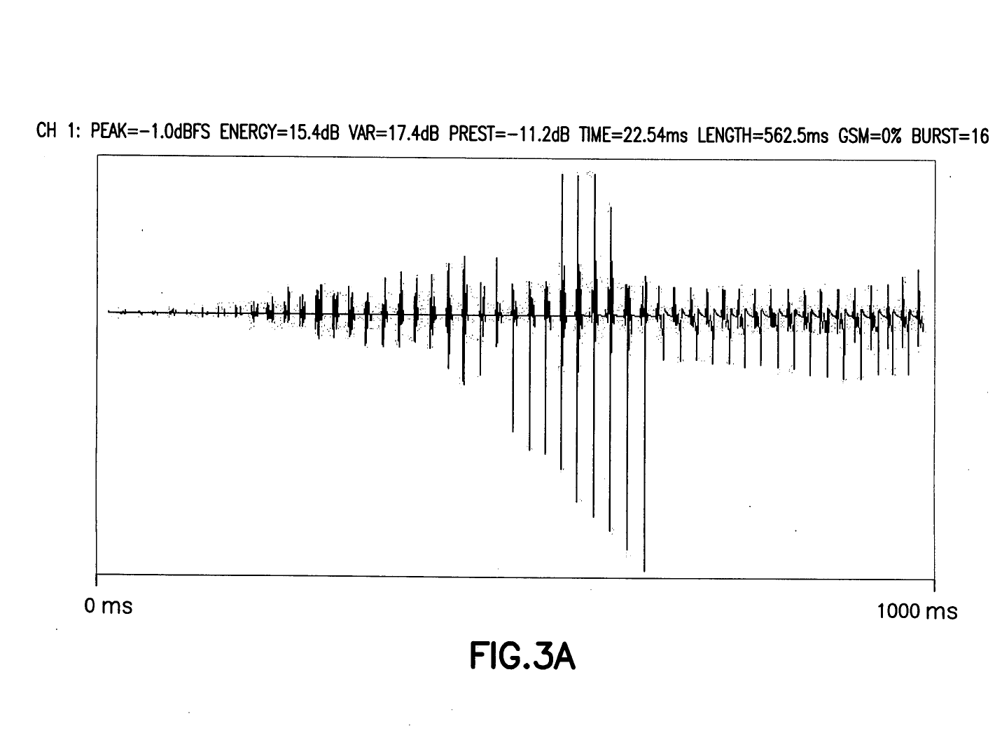

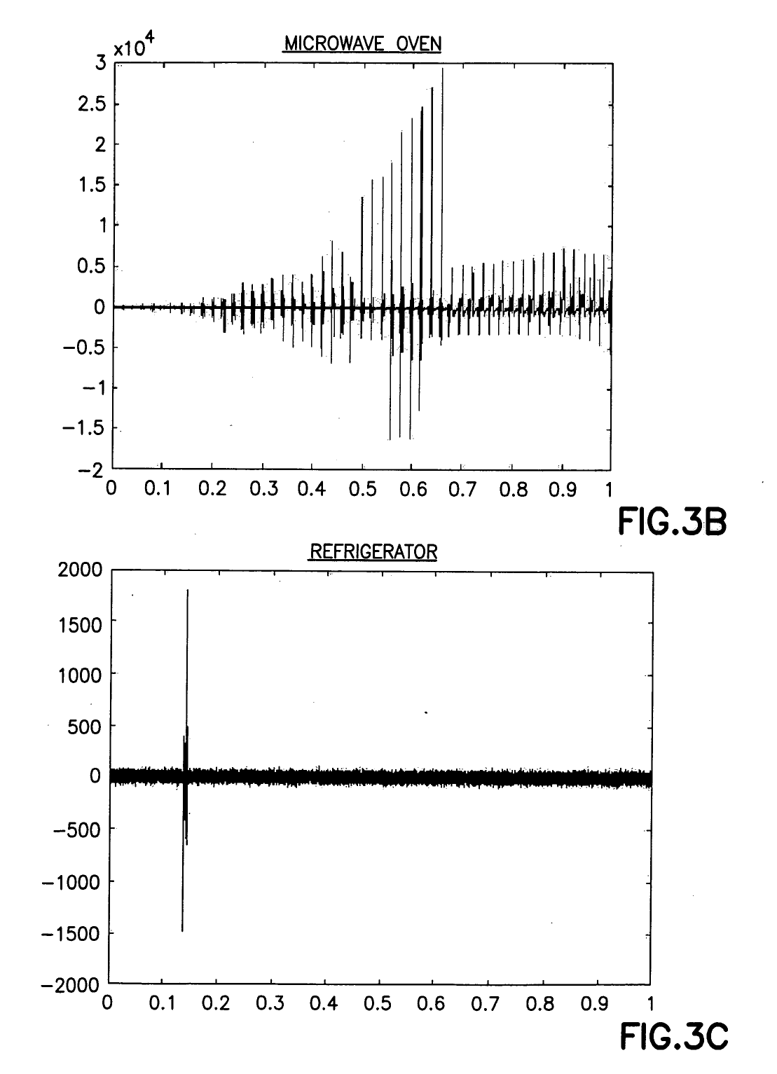

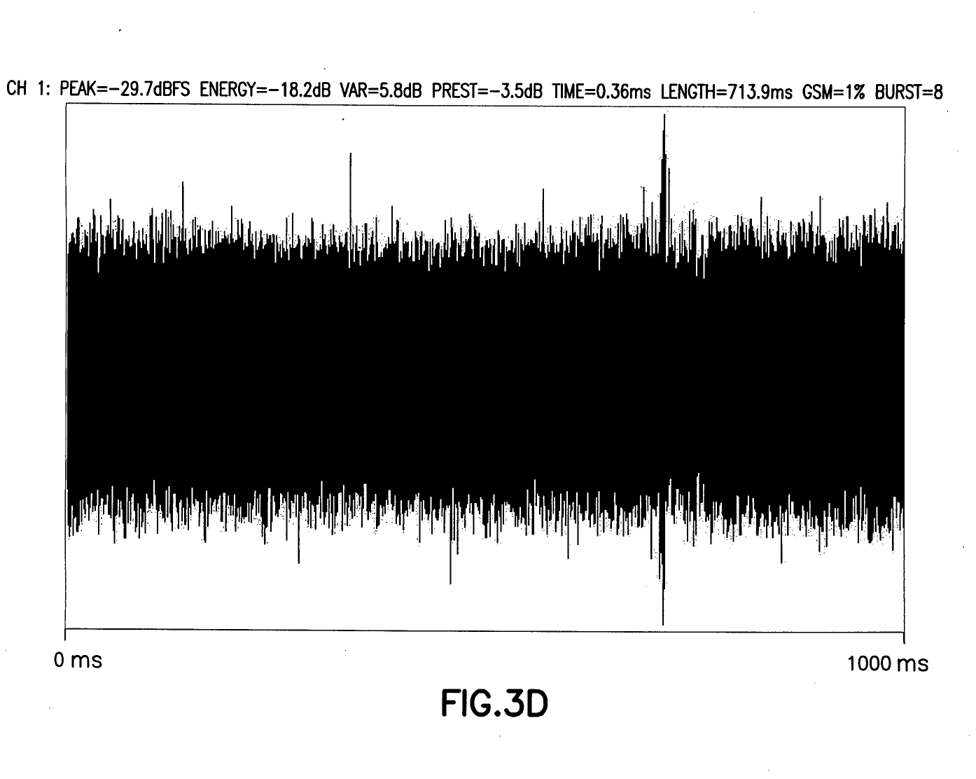

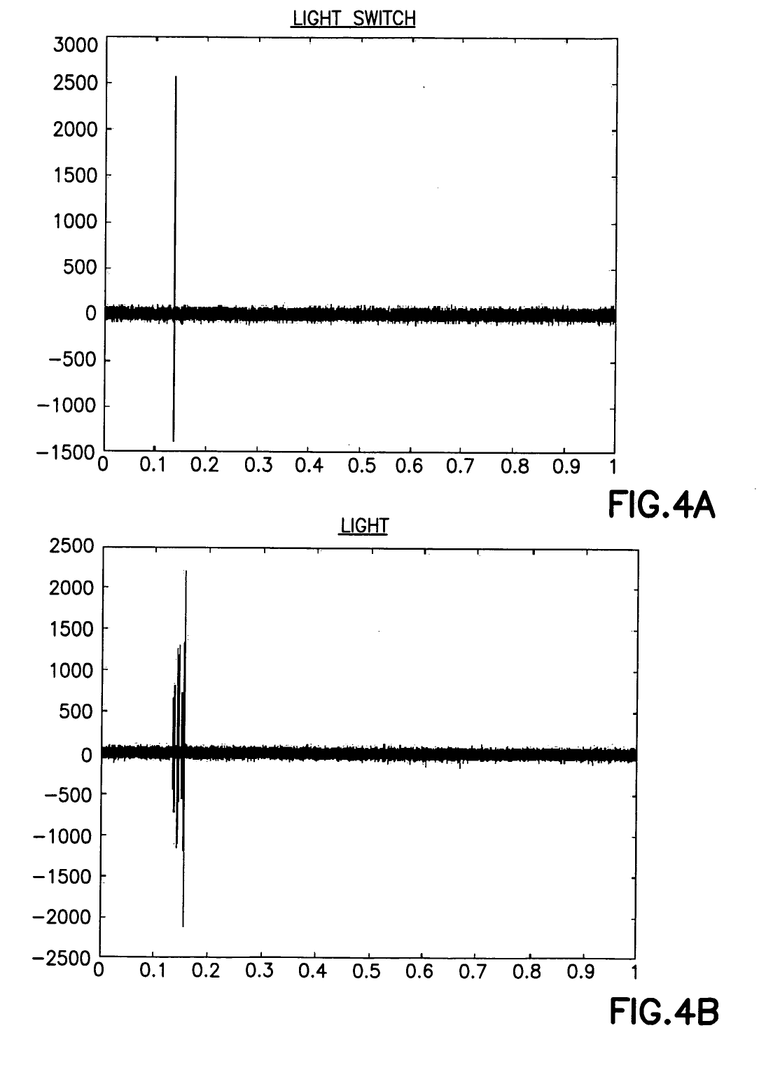

FIGS. 3A-3D and 4A-4B depict exemplary plots of interference waveforms generated from common sources (or emitters) found inside buildings. In FIG. 3A the source is a microwave oven 2 m away and in FIG. 3B the source is a different microwave oven (also at 2 m away). Note that while the sources are both microwave ovens, and their respective interference waveforms (EMI waveforms) are distinguishable from one another, the overall waveform pattern of each are similar enough to be classified as originating from same source type. The source is a refrigerator in FIG. 3C and in FIG. 3D it is an LCD monitor at less than 50 cm away. The source in FIG. 4A is a light switch which is some number of meters away. In FIG. 4B the source is a fluorescent light which is 1 m away.

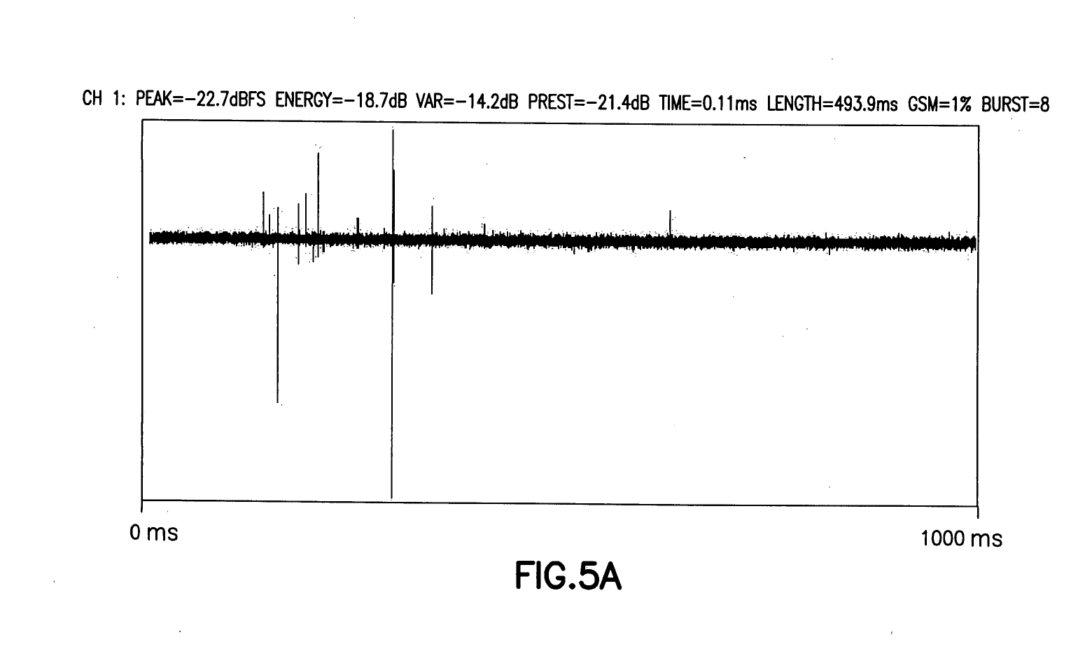

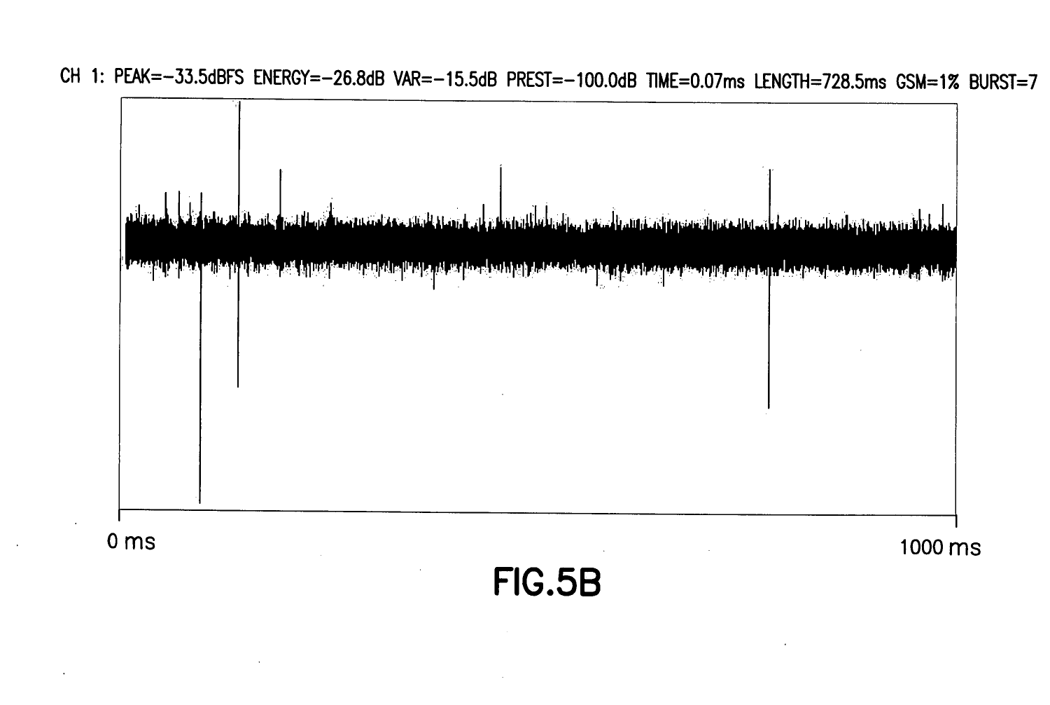

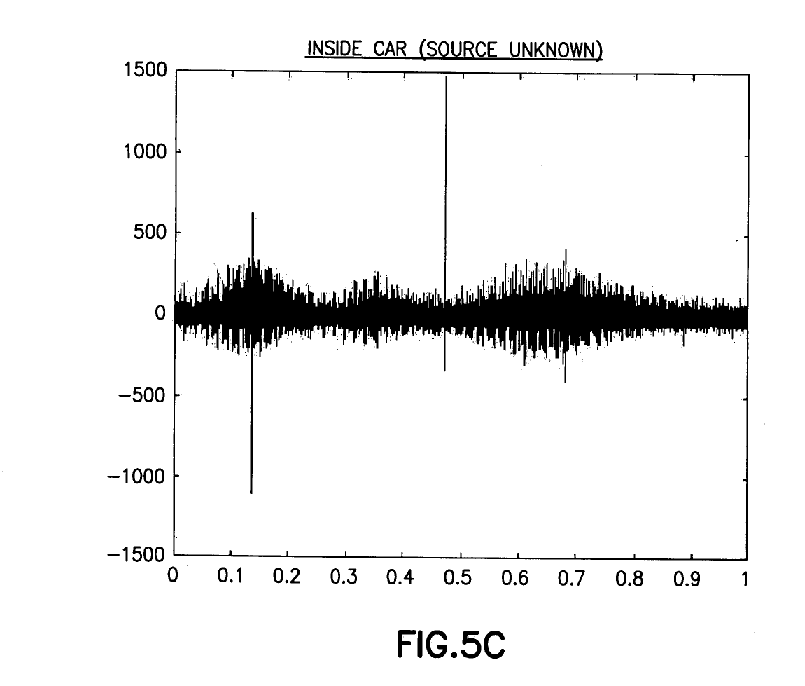

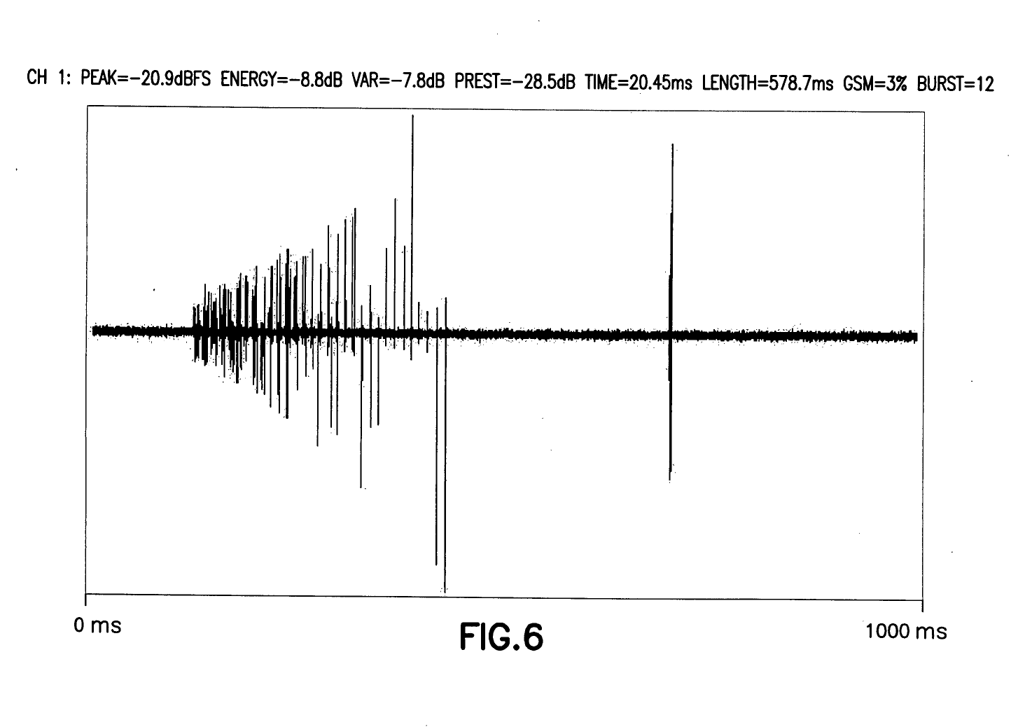

FIGS. 5A-5C and 6 depict exemplary plots of interference waveforms generated from common vehicles. The source in FIG. 5A is a car motor measured from within the car when the motor is started, and in FIG. 5B the source is measured from within a car while the engine is running. The source in FIG. 5C is also measured from within a car while the engine is running. Here the periodic waveform impressed on the signal is likely caused by operation of the windshield wipers. In FIG. 6 the source is an electric train that is 10 m away.

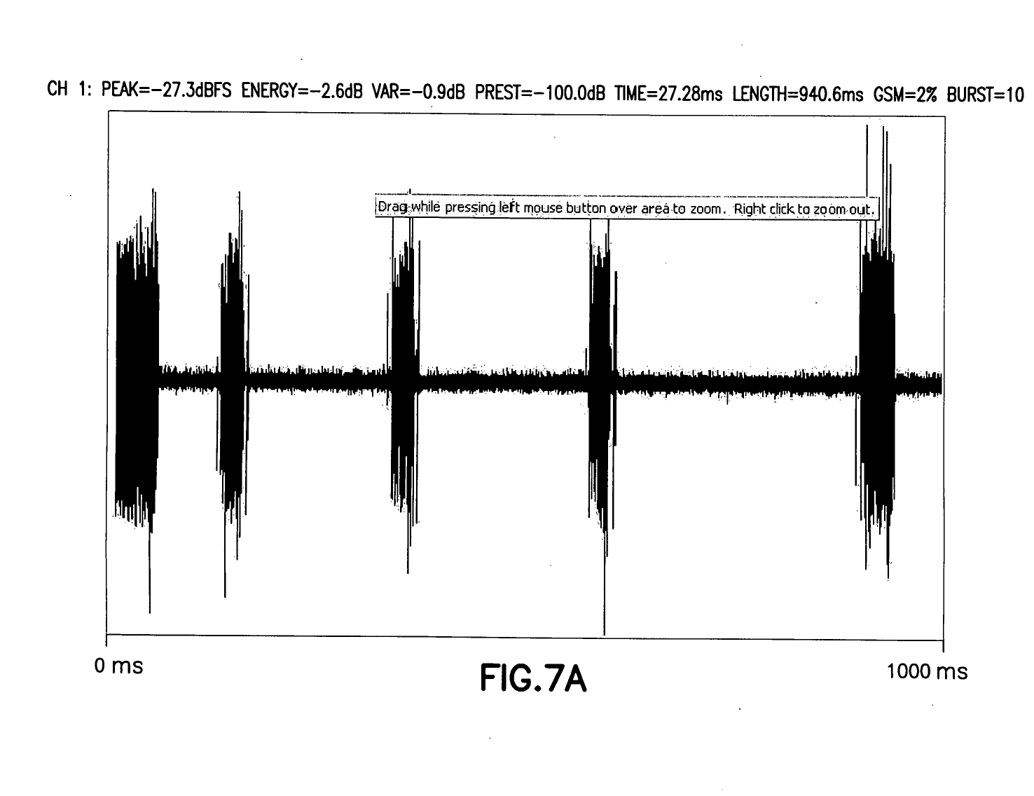

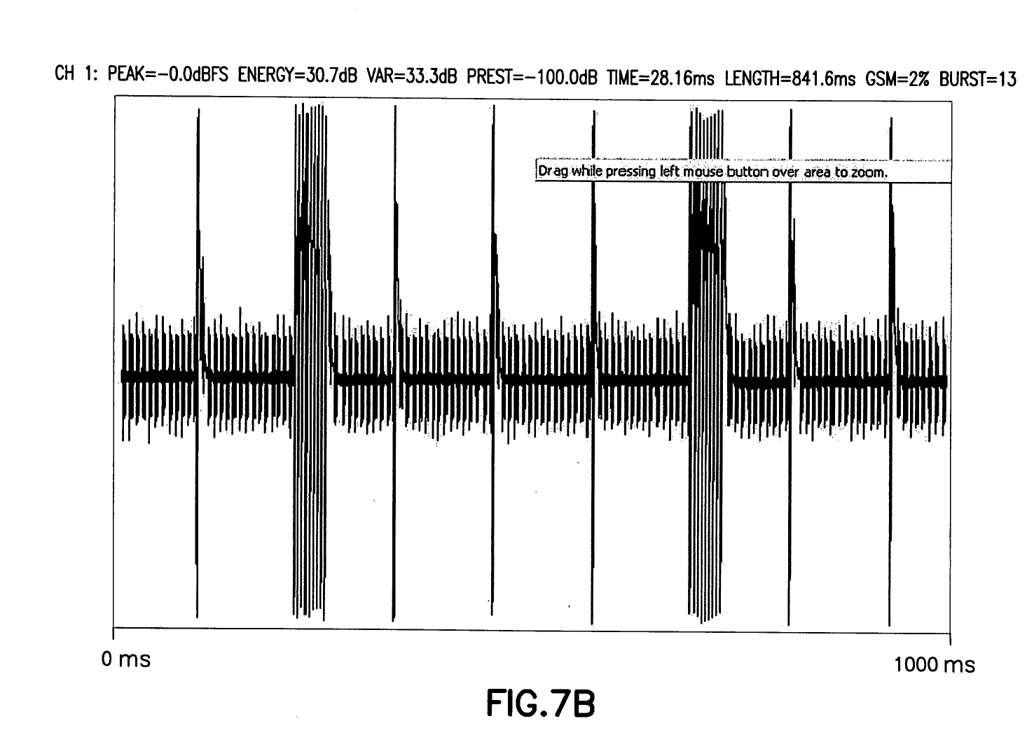

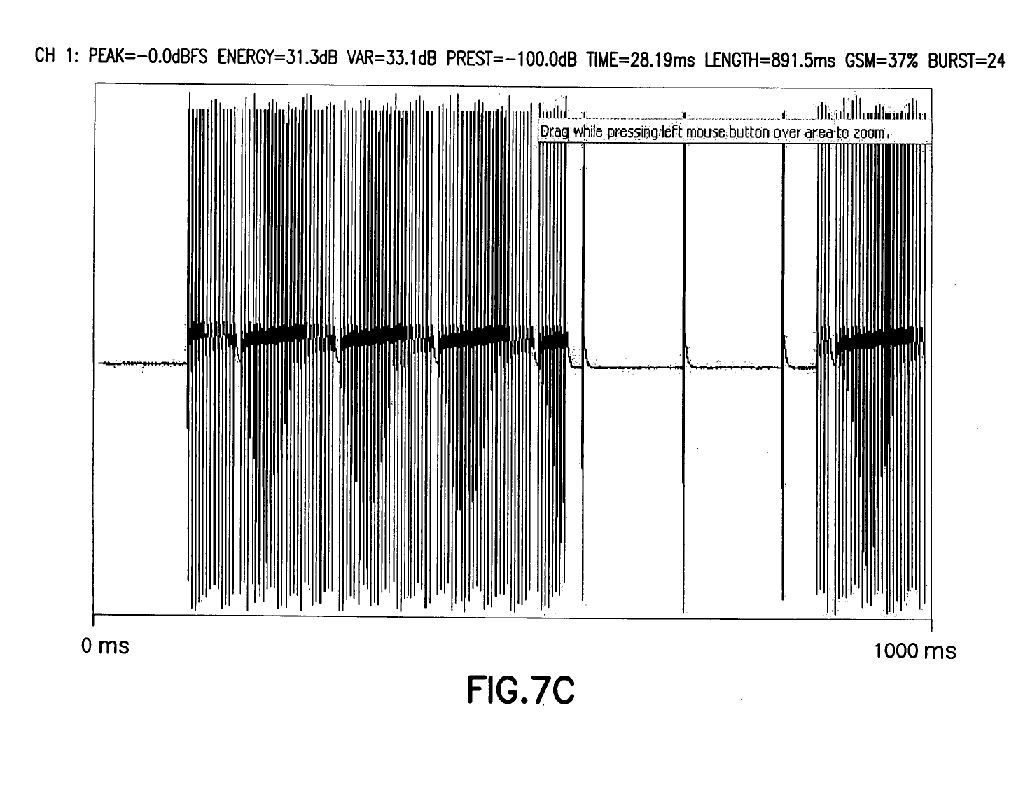

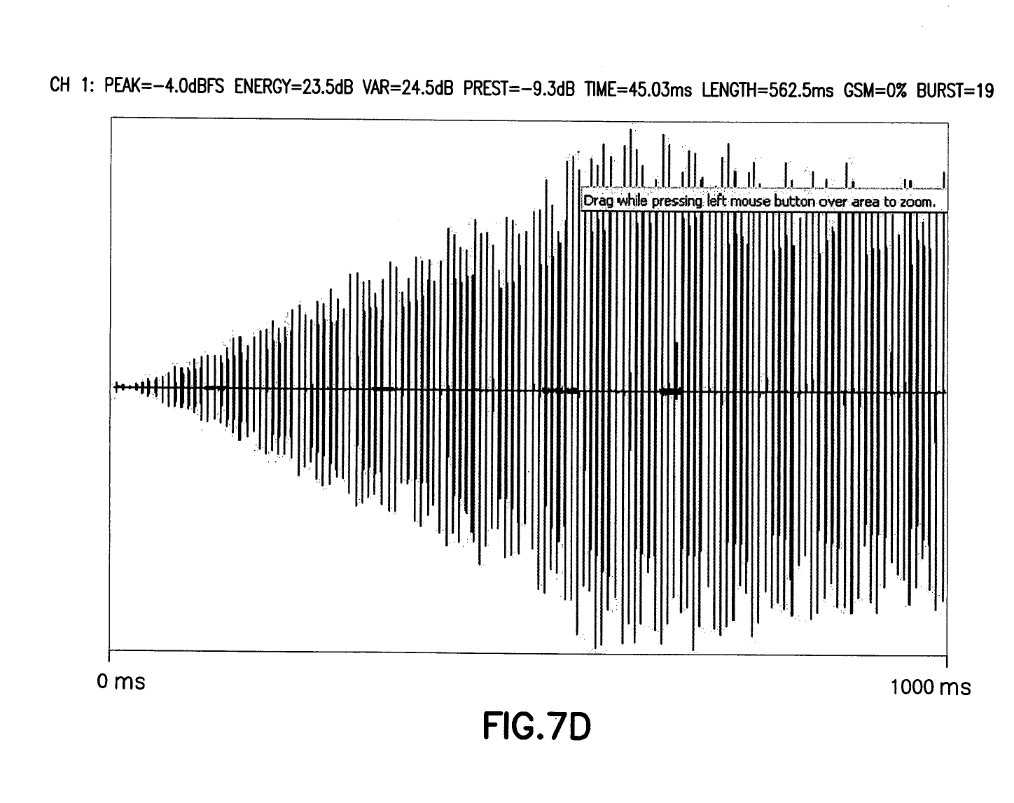

FIGS. 7A-7D depict exemplary plots of interference waveforms generated by mobile phones. In FIG. 7A the source is a GSM phone while not making a call and in FIG. 7B the GSM phone is making a call. The source is a GSM phone while in the active mode in FIG. 7C. In FIG. 7D the source is the screen of a mobile phone using a dim backlight.

In an exemplary embodiment of this invention there does not need to be an original signal S to reconstruct. Rather, the measured signal M is caused by various emitters E_i, each of which causes an EMI disturbance D_i. The measured signal is then M=sum(D_i). The goal is to determine the identity and characteristics of the emitters E_i, and not to determine the original source signals D_i as accurately as possible.

Using a defined number of “contexts” C_k, each of which is related to at least one emitter {E_i}, it is possible to determine which of the contexts C_k is most compatible with the measured signal M.

In contrast with the lightning detection system mentioned above, where any interference triggers a low-energy warning mode, and only launches the detection mode if certain preconditions are met; an exemplary embodiment of this invention may launch a full data-capture mode from every trigger, store the captured waveforms, and then compare the stored waveform or waveforms to waveforms that correspond to known interference sources. As a non-limiting example, this comparison can be done using audio-processing software. Based on an identification of the source of the captured EMI waveform(s), it is possible to deduce the context of the receiver (e.g., in a building, in a vehicle, etc.), and to then use the deduced context to perform some operation, such as controlling at least one mode of operation of a device that includes the receiver.

If an antenna is tuned to an appropriate frequency (for example in the MHz range or above), it may be prohibitively difficult, using current technology, to store and/or analyze the entire signal in the raw (unprocessed) form (as this would require a high bandwidth and a large amount of storage). However, if the signal is first downmixed to a lower frequency, for example near the audio frequency band (˜40 kHz or below), and the resulting signal is captured before any filtering (for example as an analog signal), then the resulting signal can be used to identify features in the environment, such as various types of motors. Furthermore, the envelope of the analog signal may also be used.

Exemplary embodiments of this invention may be implemented in any RF-enabled device which has audio (or similar) processing capability.

FIGS. 2-7 show exemplary sources of interference at 1 MHz. The measured waveform may be compared to stored waveforms, and the interference source may be determined by selecting a stored waveform that sufficiently matches the measured waveform. Additionally, speech-recognition algorithms may be used directly (e.g. the algorithms used to enable the user to phone someone by saying their name). These algorithms may be used for template comparison of the waveforms (and/or their envelopes).

A non-limiting example of a context may be the location of a device based upon the detected sources (or emitters) and/or a set of rules. For example, the context for a device or application may be determined to be “within a building” if one or more sources of the EMI are determined to be a microwave oven (see FIGS. 3A and 3B), a refrigerator (see FIG. 3C), or a florescent light (see FIG. 4B). The context may be determined to be “within a vehicle” if an automobile engine (see FIGS. 5A-5C), a train, or a plane engine are determined to be sources of the EMI waveform.

A context may be determined based on a plurality of source determinations performed over some period of time. For example, if more than one automobile engines (see FIGS. 5A-5C) are detected in some of several determinations, the context (e.g., a location) may be determined to be “outside, on the street”. A context may also be subdivided, for example, a context of “within a building” may be further defined as “in the office” if EMI emissions from multiple LCD screens (see FIG. 3D) are detected. Alternatively, “in the office” may be a separate context.

Once a context is determined, in a non-limiting example, the operating parameters of a mobile device may be set in accordance with the determined context. For example, if a mobile phone determines an “indoors” context it may lower the volume of a ring tone automatically, while decreasing the display backlight illumination, while if the context is determined to be “on the street”, the ring tone volume may be automatically increased in conjunction with increasing the display backlight illumination. A gaming device or a mobile communication device which determines an “on a plane” context may automatically disable its transmitter(s). As another non-limiting example, a music playing device may automatically increase the volume of the music based on determining an “on the street” context.

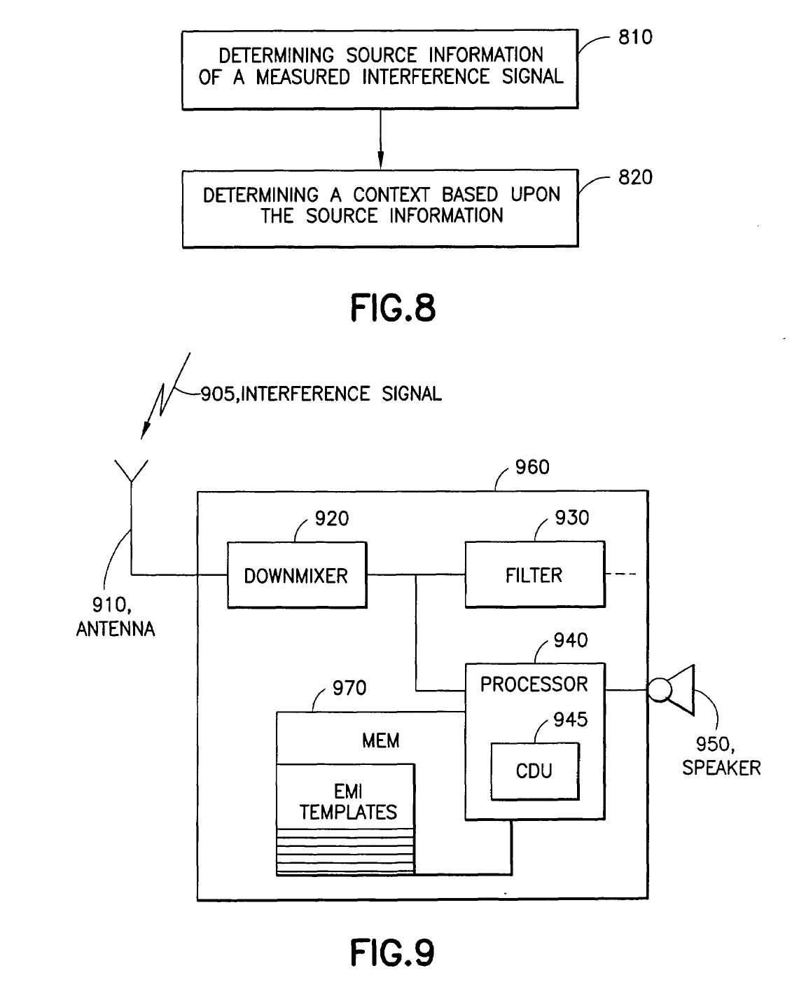

FIG. 8 shows a simplified logic flow chart of a method for determining context information using EMI patterns in accordance with this invention. At block 810 the method includes determining source information of a measured interference signal. A context is determined based upon the source information at block 820. Determining the interference signal emitter may also include comparing the measured interference signal to known interference signals. At least one setting of a device may be changed based upon the determined context.

The source information includes details about detected sources of interference. This information may include an identification of the interference source (e.g., a television, car motor, or fluorescent light) and/or may provide a distance measure to the interference source.

FIG. 9 illustrates a simplified block diagram of an electronic device 960 that is suitable for use in practicing the exemplary embodiments of this invention. Interference signal 905 is received by antenna 910 and downmixer 920 downmixes the signal to, for example, the audio band (or near to the audio band). The downmixed signal may be applied to a filter 930, or to a processor 940, which includes a context determining unit 945. Context determining unit 945 determines the source information from the downmixed interference signal and determines the context. As a non-limiting example, processor 940 may adjust the levels of signals sent to a speaker 950 based upon the determined context.

Additionally, device 960 may include a memory unit 970 which stores comparison information of known interference sources (e.g., EMI templates 970A). The memory unit 970 may also include a list of known contexts and rules for determining a context.

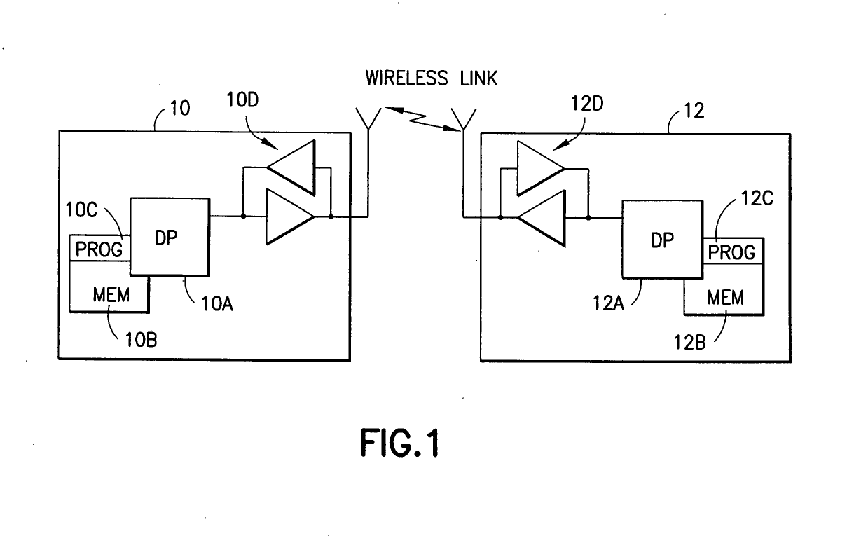

FIG. 1 shows an example of the device 960 when embedded as a mobile communication device 10. In FIG. 1 a base station 12 is adapted for communication with a mobile communication device 10. The mobile communication device 10 includes a data processor (DP) 10A, a memory (MEM) 10B that stores a program (PROG) 10C, and a suitable radio frequency (RF) transceiver 10D for bidirectional wireless communications with the base station 12, which also includes a DP 12A, a MEM 12B that stores a PROG 12C, and a suitable RF transceiver 12D.

PROG 10C may include program instructions that, when executed by the associated DP 10A, enable the device 10 to operate in accordance with the exemplary embodiments of this invention.

That is, the exemplary embodiments of this invention may be implemented at least in part by computer software executable by the DP 10A of the mobile communication device 10, or by hardware, or by a combination of software and hardware.

In general, the various embodiments of the mobile communication device 10 can include, but are not limited to, cellular telephones, personal digital assistants (PDAs) having wireless communication capabilities, portable computers having wireless communication capabilities, image capture devices such as digital cameras having wireless communication capabilities, gaming devices having wireless communication capabilities, music storage and playback appliances having wireless communication capabilities, Internet appliances permitting wireless Internet access and browsing, as well as portable units or terminals that incorporate combinations of such functions.

The MEMs 10B and 12B may be of any type suitable to the local technical environment and may be implemented using any suitable data storage technology, such as semiconductor-based memory devices, flash memory, magnetic memory devices and systems, optical memory devices and systems, fixed memory and removable memory. The DPs 10A and 12A may be of any type suitable to the local technical environment, and may include one or more of general purpose computers, special purpose computers, microprocessors, digital signal processors (DSPs) and processors based on a multi-core processor architecture, as non-limiting examples.

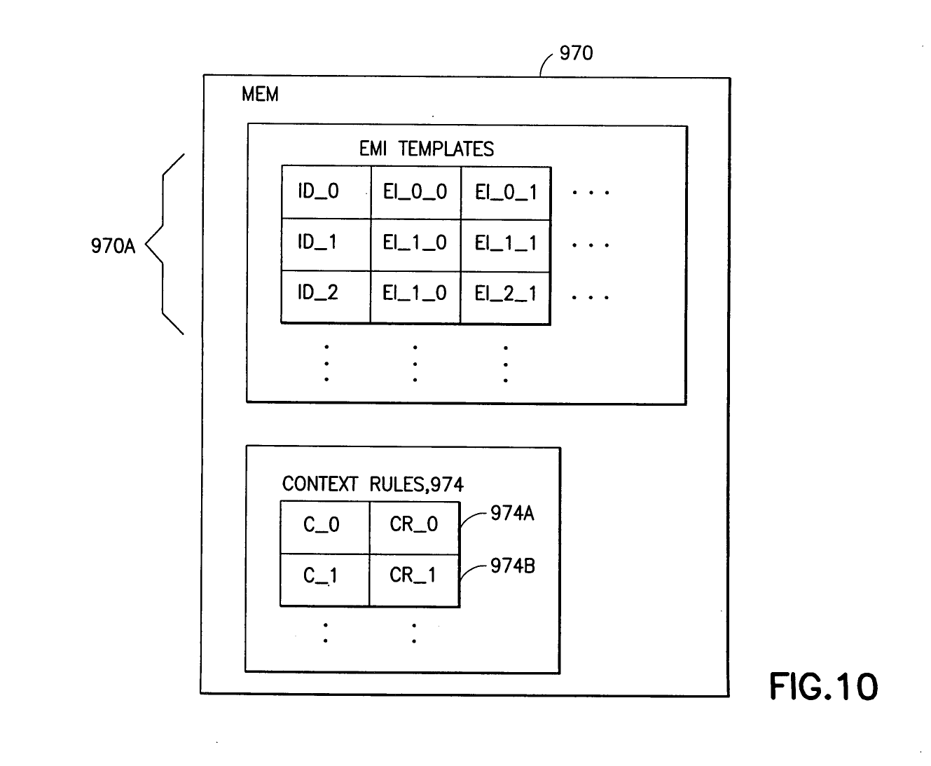

FIG. 10 shows an example of the memory unit 970. Memory unit 970 may store EMI templates 970A. The EMI templates include interference data (ID) representing an interference waveforms. Emitter information (EI) representative of a source of interference is associated to the interference data (ID). An interference data (ID) element (e.g., ID_0) may have more than one associated emitter information (EI) element (EI_0_1 and EI_0_2 in this example). Interference data (ID) may represent an audio frequency analog signal and/or the envelope of an audio frequency analog signal of an interference emitter.

Memory unit 970 may also store a set of rules 974 for determining a context. Rules (e.g., 974A and 974B) include a context (e.g., C_0) and associated context requirements (e.g., CR_0). A given context requirement may include one or more required emitter information (EI) elements.

As generally considered herein, a context describes the surroundings for an application or device. A context may describe the location and/or other circumstances of the environment. As is also generally considered herein, emitter information (EI) is descriptive of a source of interference. This information may include an identification of the emitter (e.g., an LCD screen, a fluorescent light, etc.) and/or a description of the distance to the source (e.g., a specific measure or a general category, for example, near or far). As used herein, interference refers to signals which may or may not interfere with another signal, for example such signals may be considered interference in some radio frequency communications but not in others.

An exemplary embodiment in accordance with this invention provides a method for determining context information using EMI waveform patterns. The method includes determining source information of a measured interference signal. A context is determined based upon the source information. The context may then be used to control at least one aspect of the operation of a device, such as the volume of sound produced by the device and/or an amount of illumination produced by the device, as two non-limiting examples.

In a further embodiment of the method above, the source information includes an interference signal emitter and/or a distance to the source of the interference signal.

In another embodiment of any of the methods above, determining an interference signal emitter may also include comparing a measured interference signal to known interference signals. The comparing operation may include comparing the waveform of the measured interference signal to waveforms of various known interference signals. The waveforms may be represented or be derived from audio frequency analog signals obtained by downmixing a received radio frequency signal.

In a further embodiment, the method may also include receiving a wireless signal. An interference signal contained within the wireless signal is measured and then characterized. The wireless signal may have a frequency of greater than about 1 MHz.

The determined context may be within a building, or within a vehicle, or outside of a building, or in a part of building (e.g., an office, a kitchen, a family room, etc., as non-limiting examples).

The method may also include changing at least one setting of a device based upon the determined context. The device may be a mobile device and the setting may be the volume of a user interaction sound, as one non-limiting example.

The method may be performed as a result of execution of computer program instructions stored in a computer readable memory medium.

A further exemplary embodiment in accordance with this invention provides an apparatus for determining context information using EMI waveform patterns. The apparatus includes a unit to measure at least one interference signal and a processing unit. The processing unit determines source information of the measured interference signal and determines a context based upon the source information. The context may then be used to control at least one aspect of the operation of the apparatus, such as the volume of sound produced by the device and/or an amount of illumination produced by the device, as two non-limiting examples.

In another embodiment of the apparatus above, the source information includes an interference signal emitter and/or the distance to an interference signal source.

In a further embodiment of any of the apparatuses above, the apparatus may include a memory to store known interference signals. The processing unit compares the measured interference signal to the known interference signals. The processing unit may compare the waveform of the measured interference signal to waveforms of various known interference signals. The waveforms may represent or be derived from be audio frequency analog signals obtained by downmixing a received radio frequency signal.

In another embodiment of any of the apparatuses above, the apparatus also includes a receiver to receive a wireless signal. The processing unit measures and than characterizes an interference signal contained within the wireless signal. The wireless signal may have a frequency of greater than about 1 MHz.

In a further embodiment of any of the apparatuses above, the determined context may be within a building, within a vehicle, outside of a building, or in a part of a building (e.g., an office, a kitchen, a family room, etc., as non-limiting examples).

In another embodiment of any of the apparatuses above, the processing unit also changes at least one setting of a device based upon the determined context. The device may be a mobile device and the setting may be the volume of a user interaction sound, as one non-limiting example.

A further exemplary embodiment in accordance with this invention provides an apparatus for determining context information using EMI waveform patterns. The apparatus includes a means for determining source information of a measured interference signal. A means for determining a context based upon the source information is also included. The apparatus also includes a means for setting at least one operating parameter of the apparatus.

In another embodiment of any of the apparatuses above, the apparatus includes a means for storing known interference signals. The determining means includes a means for comparing the measured interference signal to the known interference signals. The comparing means may compare the waveform of the measured interference signal to waveforms of various known interference signals. The waveforms may represent or be derived from be audio frequency analog signals obtained by downmixing a received radio frequency signal.

In a further embodiment of any of the apparatuses above, the apparatus also includes a means for receiving a wireless signal. A means for measuring an interference signal contained within the wireless signal is also included. The wireless signal may have a frequency of greater than 1 MHz.

In another embodiment of any of the apparatuses above, the apparatus may be a mobile device and the operating parameter may be the volume of a user interaction sound, as one non-limiting example.

In a further embodiment of any of the apparatuses above, the context determining means is a processing unit and the source information determining means is a processing unit.

A further exemplary embodiment in accordance with this invention provides a computer readable memory tangibly embodying a data structure for determining context information using EMI waveform patterns. The data structure includes interference data representing one or more interference waveforms. Emitter information representative of a source of interference associated with the corresponding interference data is also included. The interference data is usable with a measured interference signal to determine the emitter information. The determined emitter information is usable to determine a context of a device

In another embodiment of the computer readable memory above, the interference data represents an audio frequency analog signal. The interference data may represent an envelope of an audio frequency analog signal.

In a further embodiment of the computer readable memory above, the computer readable memory also includes at least one rule for use in establishing the context of the device.

In another embodiment of the computer readable memory above, the emitter information includes one or more identities of interference signal emitters and distances to the interference signal emitters.

It should be noted that the terms “connected,” “coupled,” or any variant thereof, mean any connection or coupling, either direct or indirect, between two or more elements, and may encompass the presence of one or more intermediate elements between two elements that are “connected” or “coupled” together. The coupling or connection between the elements can be physical, logical, or a combination thereof. As employed herein two elements may be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

The exemplary embodiments of the invention, as discussed above and as particularly described with respect to exemplary methods, may be implemented as a computer program product comprising program instructions embodied on a tangible computer-readable medium. Execution of the program instructions results in operations comprising steps of utilizing the exemplary embodiments or steps of the method.

In general, the various embodiments may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

Embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

The foregoing description has provided by way of exemplary and non-limiting examples a full and informative description of the invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention.

As employed herein the words “measured” and “measuring” may be construed to include any type of processing performed on a received signal, including digitizing the received signal and/or downconverting the received signal and/or filtering the received signal and/or any other desired operation or operations performed on the received signal.

Some of the features of the preferred embodiments of this invention could be used to advantage without the corresponding use of other features. As such, the foregoing description should be considered as merely illustrative of the principles of the invention, and not in limitation thereof.

What is claimed is:

1. A method comprising:
determining emitter information of a measured interference signal; and
determining a context based upon the emitter information.

2. The method of claim 1, wherein the emitter information comprises at least one of an identity of an interference signal emitter and a distance to the interference signal emitter.

3. The method of claim 1, wherein determining emitter information comprises comparing the measured interference signal to known interference signals.

4. The method of claim 3, wherein comparing comprises comparing a waveform of the measured interference signal to waveforms of known interference signals.

5. The method of claim 4, wherein the waveforms represent audio frequency analog signals.

6. The method of claim 1, further comprising:
receiving a wireless signal; and
measuring the interference signal contained within the wireless signal.

7. The method of claim 6, wherein the wireless signal is at least 1 MHz.

8. The method of claim 1, wherein the determined context is at least one of within a vehicle, within a building and outside of a building.

9. The method of claim 1, further comprising setting at least one operating parameter of a device based upon the determined context.

10. The method of claim 9, wherein the device is a mobile device and the at least one setting comprises the volume of a user interaction sound.

11. The method of claim 1, wherein performed as a result of execution of computer program instructions stored in a computer readable memory medium.

12. A apparatus comprising:
a unit configured to measure at least one interference signal; and
a processing unit,
wherein the a processing unit is configured to determine emitter information of the measured interference signal and to determine a context based upon the emitter information.

13. The apparatus of claim 12, wherein the emitter information comprises at least one of an interference signal emitter and a distance to the interference signal emitter.

14. The apparatus of claim 12, further comprising:
a memory configured to store data representing at least one known interference signal for use in determining emitter information of the measured interference signal.

15. The apparatus of claim 14, wherein the processing unit is further configured to compare a waveform of the measured interference signal to waveforms of the known interference signals.

16. The apparatus of claim 15, wherein the waveforms represent audio frequency analog signals.

17. The apparatus of claim 12, further comprising:
a receiver configured to receive a wireless signal,
wherein the processing unit is configured to measure the interference signal contained within the wireless signal.

18. The apparatus of claim 16, wherein the wireless signal is at least 1 MHz.

19. The apparatus of claim 12, wherein the determined context is selected from a list comprising: within a car and within a building.

20. The apparatus of claim 12, wherein the processing unit is further configured to set at least one operating parameter of a device based upon the determined context.

21. The apparatus of claim 20, wherein the device is a mobile device and the at least one setting comprises the volume of a user interaction sound.

22. A apparatus comprising:
means for determining emitter information of a measured interference signal;
means for determining a context based upon the emitter information; and
means for setting at least one operating parameter of the apparatus in response to the determined context.

23. The apparatus of claim 22, further comprising:
means for storing data representing at least one known interference signal for use in determining emitter information of the measured interference signal.

24. The apparatus of claim 22, further comprising:
means for receiving a wireless signal; and
means for measuring the interference signal contained within the wireless signal.

25. A computer readable memory tangibly embodying a data structure comprising:
interference data representing at least one interference waveform; and
emitter information representative of a source of interference associated with the corresponding interference data,
wherein the interference data is configurable to be used with a measured interference signal to determine the emitter information,
wherein the determined emitter information is configurable to be used to determine a context of a device.

26. The memory unit of claim 25, wherein the interference data represents an audio frequency analog signal.

27. The memory unit of claim 26, wherein the interference data represents an envelope of an audio frequency analog signal.

28. The memory unit of claim 25, further comprising at least one rule for use in establishing the context of the device.

29. The memory unit of claim 25, wherein the emitter information comprises at least one of an identity of an interference signal emitter and a distance to the interference signal emitter.
